(19) United States
(12) Patent Application Publication
(10) Pub. No.: US 2009/0061074 A1
(43) Pub. Date: Mar. 5, 2009

(54) TECHNOLOGY OF DETECTING ABNORMAL OPERATION OF PLASMA PROCESS

(75) Inventors: Masahiro Takizawa, Tokyo (JP); Takashi Wada, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 12/266,326

(22) Filed: Nov. 6, 2008

Related U.S. Application Data
(62) Division of application No. 11/134,774, filed on May 20, 2005.

(51) Int. Cl. C23C 16/52

(52) U.S. Cl. 427/8

(57) ABSTRACT

A method of detecting abnormal operation of a plasma process, includes: (i) detecting a potential Vpp1 between an upper electrode and a lower electrode disposed parallel to each other in a reaction camber at a time T1 after the plasma process begins in the reaction chamber; (ii) detecting a Vpp2 between the upper electrode and the lower electrode at a time T2 after T1; (iii) comparing Vpp1 and Vpp2 to obtain an operation value; and (iv) determining abnormal operation if the operation value is within a predetermined range.

### CROSS-REFERENCE TO RELATED APPLICATIONS

This application is a divisional of U.S. patent application Ser. No. 11/134,774, filed May 20, 2005, the disclosure of which is herein incorporated by reference in its entirety.

### BACKGROUND OF THE INVENTION

1. Field of the Invention

This invention relates to a plasma processing apparatus used for depositing films on semiconductor wafers, etc., and to a method to diagnose cleaning processes.

2. Description of the Related Art

Chemical Vapor Deposition (hereinafter referred to as “CVD”) is a processing method widely used in the semiconductor industry. In a CVD process, chemical reaction of various gases inside a reaction chamber cause a film to be deposited on semiconductor wafer substrates. In order to deposit a film on substrates at low temperature and high speed inside the reaction chamber, a plasma gas can be generated in a deposition step. This process is called “Plasma Enhanced Chemical Vapor Deposition” (hereinafter referred to as “PECVD”).

In a deposition process, films also deposit on the interior walls of the reaction chamber and other parts inside the chamber, and cause particles to generate. If these particles get onto substrates, they can have significant negative effects on the semiconductor manufacturing process that involves very minute components and structures. Therefore, these contaminating particles must be removed.

For the above reason, the reaction chamber used in a PECVD process must be regularly cleaned to remove the films deposited in the preceding deposition process. Normally, this cleaning process is implemented by flushing the reaction chamber with NF₃ or other fluorine gas.

However, this cleaning process is not always implemented normally, and cleaning sometimes occurs late or too early for various reasons (such as when the films deposited inside the chamber are thicker or thinner than normal). In this case, the cleaning process may not complete within the specified time (under-cleaning) or the chamber may be cleaned excessively (over-cleaning). In the event of under-cleaning, which indicates insufficient cleaning, the unnecessary films deposited on the interior walls of the reaction chamber, on the showerhead, etc., cannot be thoroughly removed. The residual films will affect the subsequent film deposition processes and reduce the properties of produced films.

To address this problem, a solution can be proposed in which the cleaning step in the recipe is set long from the beginning. However, if cleaning completes normally, a long cleaning step results in over-cleaning and may damage the parts inside the reaction chamber. A long cleaning step also prolongs the recipe execution time, which in turn reduces the number of wafers that can be processed per unit time (throughput). Furthermore, since fluorine gases used for cleaning the reaction chamber are expensive, setting a long cleaning step can be a costly exercise.

In view of the problems mentioned above, methods to automatically detect an endpoint of an etching or cleaning process have been proposed, including the one disclosed in Published Japanese Translation of PCT International Patent Application No. 2003-521807.

This method detects an endpoint of etching or cleaning by continuously and simultaneously monitoring at least one condition, but preferably two or three processing conditions, being selected from: power supply, forward RF power, RF reflected power, RF matching component, RF peak-to-peak voltage/current and phase component, DC bias and chamber pressure. In addition, this method determines an endpoint using two processing conditions (first and second processing conditions).

In this case, the first processing condition is continuously monitored and when an endpoint is detected under the first processing condition, the other processing condition, or the second processing condition, is used to confirm that the detected endpoint is correct, in order to improve the accuracy of endpoint judgment. In other words, whether the endpoint detected by the first processing condition is correct or not is determined based on whether or not the result obtained by the second processing condition corresponds to a predetermined value or falls within a predetermined range. If the result obtained by the second processing condition does not correspond to a predetermined value or fall within a predetermined range, an “error flag” is set and an error is recognized.

Under this technology, however, no “error flag” is issued under the second processing condition if the etch rate or cleaning rate is low and an endpoint is not detected under the first processing condition. As a result, the process continues until it is stopped by an external means. This leads to under-etching or under-cleaning. Even when the etch rate or cleaning rate is normal, no “error flag” is issued under the second processing condition if an endpoint is not detected under the first processing condition for some other reason. As a result, the process also continues until it is stopped by an external means. This leads to over-etching or over-cleaning, which may result in damaged parts and lower throughput.

If the various signals are monitored using control software, use of an online system increases the loads on the host computer and apparatus controller PC because monitor commands must be issued continuously.

Furthermore, the endpoint condition may not be the same for all film types, so the first and second processing conditions must be predetermined for each type of target film. As a result, the settings must be changed every time the type of target film is changed.

### SUMMARY OF THE INVENTION

The present invention was developed in light of the problems explained above. It is the object of one embodiment of the present invention to provide a technology to diagnose abnormal operation of a cleaning process or film deposition process in an accurate and simple manner by means of detecting abnormal condition occurring in the cleaning process or film deposition process through discontinuous detections of one type of signal.

It is the object of another embodiment of the present invention to provide a technology to diagnose abnormal operation of a cleaning process or film deposition process that is not limited to certain types of film or that can be applied universally to films of multiple types.

It is the object of yet another embodiment of the present invention to provide a technology to issue a warning and immediately stop the cleaning process or wafer lot processing, when abnormal operation is detected, so that no more defective wafers will be manufactured.

It is the object of yet another embodiment of the present invention to provide a technology to diagnose abnormal operation that can be applied in addition to a conventional technology by forcing virtually no changes to a system that uses such conventional technology.

In one embodiment of the present invention that achieves one or more of the objectives explained above, the voltage applied between the electrodes in the reaction chamber is measured in a cleaning process or film deposition process on a plasma processing apparatus. By comparing the voltages measured at two chronological points (or three or more noncontiguous or intermittent points depending on the specific embodiment) during the target process, whether or not the cleaning process or film deposition process was implemented normally is determined. In one embodiment, a warning is issued and the cleaning process or film deposition process and wafer lot processing are immediately stopped, if a problem occurs, so that no more defective wafers will be manufactured.

Here, the voltage applied between the electrodes in the reaction chamber when plasma is enhanced in a cleaning process or film deposition process is called “Vpp.” Solid line A in FIG. 1 is an example of behavior of Vpp during a normal cleaning process.

The behavior of Vpp sometimes draws a curve, as indicated by dotted line B in FIG. 1, for some reason. Compared with the normal pattern indicated by the solid line, the Vpp peak of the curve is clearly shifted. Specifically, this indicates that the cleaning rate was low and the cleaning process did not complete within the time shown in FIG. 1 (abnormal operation of the cleaning process).

In one embodiment, a plasma processing apparatus proposed by the present invention measures Vpp voltages at two chronological points during a cleaning step in a recipe when a problem of low cleaning rate occurs, as indicated by the dotted line in FIG. 1, and uses the relationship of the measured voltages to determine if the cleaning process was implemented normally. If the cleaning process was not implemented normally, the process is stopped immediately.

The above method allows for detection of abnormal operation of the reaction chamber during a cleaning process and immediate stopping of the process, so that no more defective wafers will be manufactured.

Since measurement is taken at two chronological, noncontiguous points, the loads on the host computer and apparatus controller PC can be reduced.

Since the judgment of whether or not a process was implemented normally is determined only via comparison of measured Vpp voltages, the control software can also be simplified.

Abnormal operation can also be detected in a film deposition process by measuring Vpp, just like in a cleaning process, and the same controls can be implemented.

For purposes of summarizing the invention and the advantages achieved over the related art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes.

FIG. 1 is a graph showing a typical behavior of Vpp voltage during a cleaning process on a plasma processing apparatus and a behavior of Vpp voltage when the reaction chamber is abnormal.

FIG. 2 is a flow chart showing the function to detect abnormal operation during a cleaning process on a plasma processing apparatus in one embodiment of the present invention.

FIG. 3 is a drawing showing the configuration of a plasma processing apparatus used in one embodiment of the present invention.

FIG. 4 is a graph showing a typical behavior of Vpp voltage during a deposition process on a plasma processing apparatus and a behavior of Vpp voltage when the reaction chamber is abnormal.

FIG. 5 is a flow chart showing the function to detect abnormal operation during a deposition process on a plasma processing apparatus in one embodiment of the present invention.

FIG. 6 is a schematic drawing of a control system of a plasma processing apparatus used in one embodiment of the present invention.

### DETAILED DESCRIPTION OF THE PREFERRED EMBODIMENT

The present invention includes, but is not limited to, the following embodiments which can achieve one or more of the objects described above:

A method of detecting abnormal operation of a plasma process comprises: (i) detecting a potential Vpp1 between an upper electrode and a lower electrode disposed parallel to each other in a reaction camber at a time T1 after the plasma process begins in the reaction chamber; (ii) detecting a Vpp2 between the upper electrode and the lower electrode at a time T2 after T1; (iii) comparing Vpp1 and Vpp2 to obtain an operation value; and (iv) determining abnormal operation if the operation value is within a predetermined range.

The above embodiment can further include the following embodiments:

The plasma process may be a cleaning process. Inner surfaces of the reaction chamber are exposed to a plasma during film formation, and unwanted accumulation of particles occurs thereon, especially on a surface of the upper electrode. The accumulated particles are removed through the cleaning process. The cleaning of an surface of the upper electrode is particularly important with respect to quality of deposited films. In an embodiment, by applying an electric voltage between the upper electrode and the lower electrode and measuring Vpp, it is possible to determine progress of the cleaning especially with respect to the surface of the upper electrode.

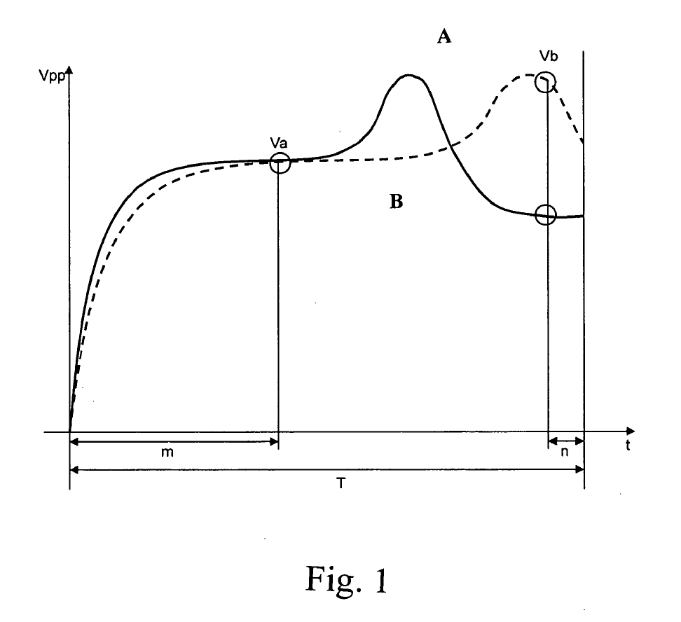

As explained above, an example of behavior of Vpp during cleaning is indicated in FIG. 1. In the beginning of cleaning, the upper electrode surface is covered with a deposited insulation film, and Vpp is low. As cleaning progresses, the insulation film is being removed from its outmost surface, and Vpp increases. The thickness of the insulation film is getting lower. Because the plasma density (in in-situ cleaning) or the gas (i.e., radical) density (in remote plasma cleaning) near a periphery of the upper electrode is lower than its center, the etch rate at the center is greater than that at the periphery. When the insulation film is getting thinner and then removed at the center, Vpp reaches a highest point (a peak). Thereafter, the removal of the insulation film spreads from the center toward the periphery, and Vpp decreases. When the insulation film is completely removed, Vpp becomes stable. Note that the above theory is tentative and is not intended to limit the present invention.

If the etch rate is low for some reasons such as unanticipated thickness of a deposited film, the peak is shifted, i.e., the cleaning may not be complete within a predetermined time (T). Thus, by comparing Vpps before and after the peak, it is possible to determine whether the cleaning process operation is normal or abnormal. In an embodiment, T1 is at or near a midpoint of the cleaning process, which is time “m”, and T2 is at or near an endpoint of the cleaning process, which is time “T−n”. In FIG. 1, Vpp at time “m” is Va (Vpp1), and Vpp at time “T−n” is Vb (Vpp2).

In the above, in an embodiment, if Vpp2<Vpp1, it can be determined that the cleaning operation is normal, whereas if Vpp2≧Vpp1, it can be determined that the cleaning operation is abnormal. T, m, and n may be predetermined through experiments. In an embodiment, n is about 0% to about 20% of T (in another embodiment about 5% to about 15% of T) which corresponds to a second stable (plateau) value of Vpp. Alternatively, in an embodiment, the absolute value of a difference between Vpp2 and Vpp1 (|Vpp2−Vpp1|) can be used to determine the operation condition. For example, if |Vpp2−Vpp1|≦a threshold value, the operation can be determined to be abnormal. The threshold value can be predetermined through experiment. In another embodiment, a ratio of Vpp2 to Vpp1 (Vpp2/Vpp1) can be used to determine the operation condition.

The above-explained behavior of Vpp during cleaning can be common to various types of insulation films deposited on the upper electrode surface. Thus, software which is programmed to execute the above determination procedures can be used universally.

In the above, in an embodiment, the upper electrode is a showerhead, and the lower electrode is a susceptor, and the cleaning process is remote plasma cleaning. Conventionally, during remote plasma cleaning, no electric voltage is applied between the upper electrode and the lower electrode in order to avoid damage to the upper electrode surface. In an embodiment, even during remote plasma cleaning, an electric voltage is applied between the upper electrode and the lower electrode for detecting Vpp1 and Vpp2. If the cleaning is in situ cleaning, the electric voltage applied between the upper electrode and the lower electrode for cleaning can also be utilized for the purposes of detection of abnormal operation. In an embodiment, the upper electrode and the lower electrode can be additionally provided in the reaction chamber which are not used for film deposition or cleaning but used for detection of abnormal operation.

In an embodiment, an electric voltage applied between the upper electrode and the lower electrode may be in the range of about 500 W/m² (of the upper electrode surface) to about 2000 W/m², preferably about 800 W/m² to about 1500 W/cm². In an embodiment, the distance between the upper electrode and the lower electrode may be in the range of about 5 mm to about 30 mm, preferably about 10 mm to about 25 mm. The above-described principle can be applied to any types of reaction chamber which involves plasma CVD.

Further, in an embodiment, more than two Vpp detecting points (the above two plus one or two or more additional points) can be selected as long as Vpp is not continuously measured. By detecting Vpp intermittently, a system load can be minimized. Except for the time of detecting Vpp, a timer can be the only unit activated. Other functions need not be activated until they are called by the timer.

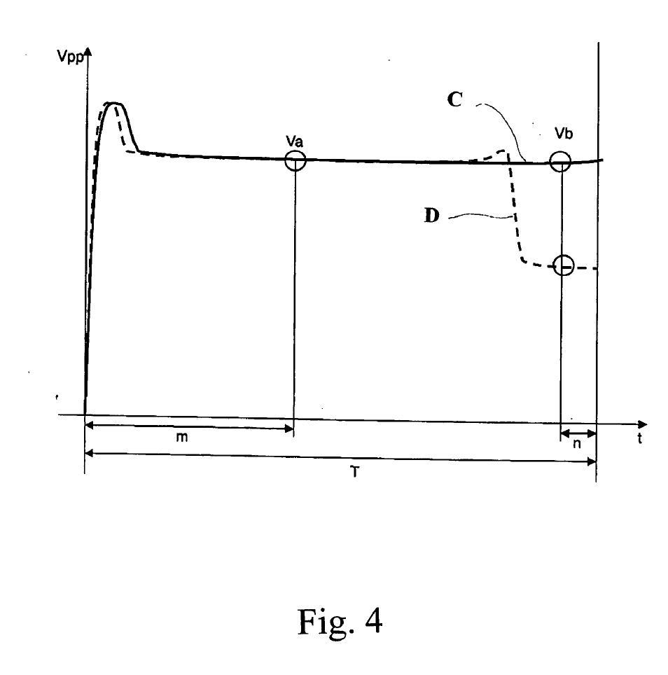

In another embodiment, the plasma process is a film deposition process. The above-described principle of detecting abnormal operation can be applied to a film deposition process. FIG. 4 shows an example of behavior of Vpp during a film deposition process. In FIG. 4, Vpp is a potential between the upper electrode and the lower electrode on which a substrate is placed. In the beginning of film deposition, Vpp quickly increases by analogue response and reaches a highest point (peak) due to residual effect. Thereafter, Vpp drops and becomes stable. If the operation is abnormal for some reasons such as abnormal plasma discharge during deposition, Vpp drops near the endpoint of a predetermined time period (T). Thus, by comparing Vpps before and after the drop, it is possible to determine whether the film deposition process operation is normal or abnormal. In an embodiment, T1 is at or near a midpoint of the film deposition process, which is time “m”, and T2 is at or near an endpoint of the film deposition process, which is time “T−n”. In FIG. 4, Vpp at time “m” is Va (Vpp1), and Vpp at time “T−n” is Vb (Vpp2).

In the above, in an embodiment, if Vpp2≈Vpp1 (≈ means approximately or nearly the same in practical sense, allowing ordinary deviations such as a difference caused by electric noise), it can be determined that the film deposition operation is normal, whereas if Vpp2<Vpp1, it can be determined that the film deposition operation is abnormal. In an embodiment, the absolute value of a difference between Vpp2 and Vpp1 (|Vpp2−Vpp1|) can be used to determine the operation condition. For example, if |Vpp2−Vpp1|≧a threshold value, the operation can be determined to be abnormal. The threshold value can be predetermined through experiment. T, m, and n may be predetermined through experiments. Alternatively, in an embodiment, a ratio of Vpp2 to Vpp1 (Vpp2/Vpp1) can be used to determine the operation condition. An electric voltage applied between the upper electrode and the lower electrode for film deposition can also be used for detecting abnormal operation; otherwise, the aforesaid electric voltage used for detecting abnormal operation of cleaning can be used.

The above-explained behavior of Vpp during film deposition can be common to various types of films deposited on a substrate. Thus, software which is programmed to execute the above determination procedures can be used universally.

In an embodiment, regardless of whether the plasma process is cleaning or film deposition, the method may further comprise stopping the plasma process when the abnormal operation is detected. It can be accomplished by transmitting a signal to a host computer which operates the plasma process when software determines abnormal operation. The software can be installed separately from the host computer. Alternatively, abnormal operation can also be determined by the host computer.

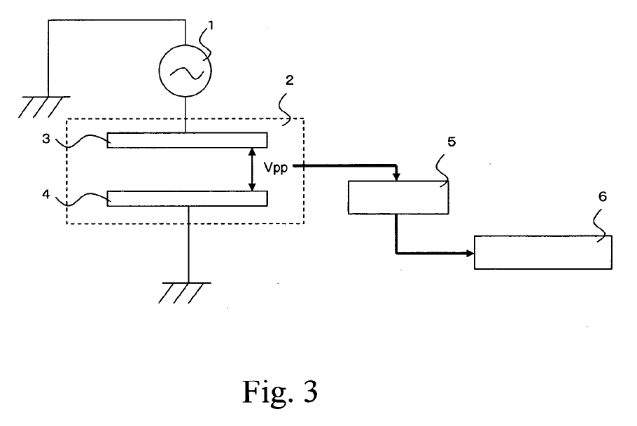

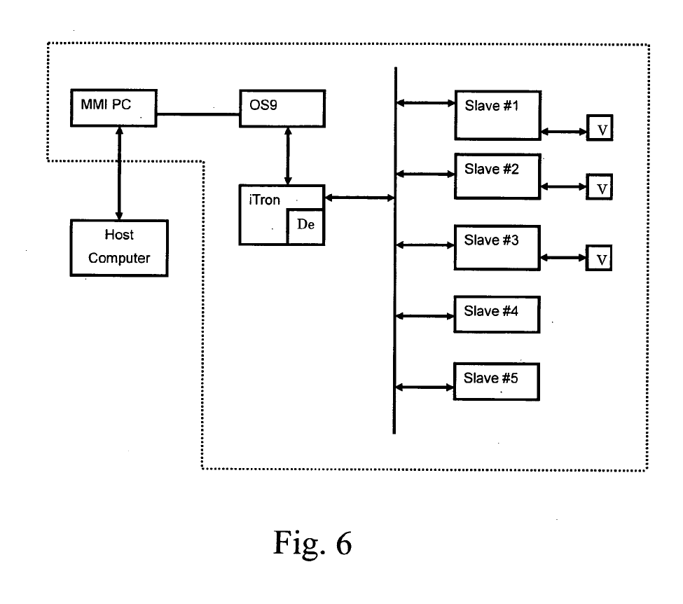

FIG. 6 is a schematic drawing showing an embodiment of a control system for a cluster type plasma CVD apparatus. In this figure, Slaves #1 to #5 are CPU boards for controlling each elements. Slave #1 to #3 are installed for Reactors #1 to #3, Slave #4 is installed for an atmospheric robot, and Slave #5 is installed for a vacuum robot in a wafer transferring section. V is a Vpp detection unit (see FIG. 3 which will be explained later). The Vs are connected to Slaves #1 to #3, respectively. iTron is a CPU board of a main controller which controls all plasma operation (e.g., recipe operation control) including cleaning and film deposition. De is software for detecting abnormal operation based on Vpp and stopping the abnormal operation through the iTron. De can control both cleaning and film deposition. MMI PC is a PC for a man-machine interface which is connected to a host computer. OS9 is a CPU board for communication with the MMI PC. T1, T2, and a threshold for |Vpp2−Vpp1|, for example, can be set and inputted using the MMI PC. In this figure, the De is installed in the iTron, but De can be installed as an addition to the host computer. Thus, controlling the abnormal operation detection system does not substantially reduce the capacity of the main computer. In this figure, the elements enclosed by the dotted line may constitute a plasma CVD system which is connectable to a host computer of a user. In the above, “connection” may include physical, electrical, functional, direct, or indirect connection depending on the individual application.

In another aspect, the present invention provides a plasma CVD apparatus comprising: (i) a reaction chamber for plasma CVD provide with an upper electrode and a lower electrode disposed parallel to each other; and (ii) a system for detecting abnormal operation of a plasma process in the reaction chamber, said system being programmed to: (a) detect a potential Vpp1 between the upper electrode and the lower electrode at a time T1 after the plasma process begins in the reaction chamber; (b) detect a Vpp2 between the upper electrode and the lower electrode at a time T2 after T1; (c) compare Vpp1 and Vpp2 to obtain an operation value; and (d) determine abnormal operation if the operation value is within a predetermined range. The above mentioned elements with regard to the methods can equally be applied to the apparatuses.

In all of the aforesaid embodiments including the methods and the apparatuses, any element used in an embodiment can interchangeably be used in another embodiment unless such a replacement is not feasible or causes adverse effect.

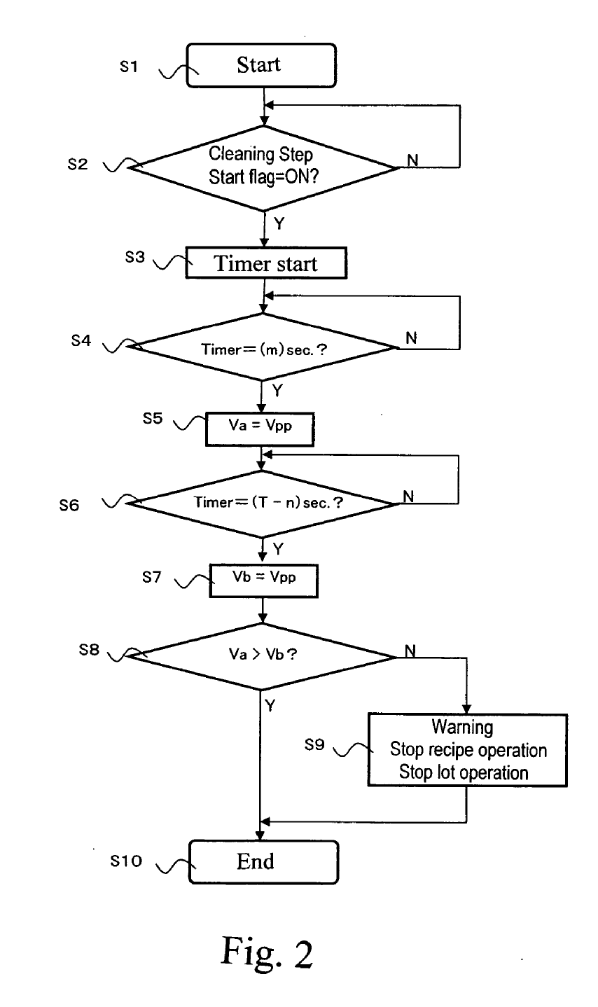

FIGS. 2 and 3 illustrate a sample cleaning control process on a plasma processing apparatus used in some embodiments of the present invention. It should be noted, however, that the present invention is not at all limited to these drawings and embodiments.

In FIG. 2, the control process comprises the 10 steps explained below. The process starts in step 1, and whether the currently executed portion of the recipe is a cleaning step or not is determined in step 2. Here, it is assumed that the recipe contains software flags that are used to identify special steps such as deposition and cleaning, wherein each flag is set (a variable turns “ON”) when the corresponding step is started. If the cleaning step flag is not yet set in step 2, the software program does not proceed to the subsequent steps and continues to wait for the flag to be set. If the flag is already set, the software program proceeds to step 3. In step 3, a timer is started to measure predefined periods of m seconds and n seconds. Here, the specified values of m and n may be typical periods that are determined by experimental data. In step 4, whether m seconds have elapsed or not on the timer is determined. If m seconds have not yet elapsed, the software program stays in step 4 until m seconds elapse. Once m seconds have elapsed, the software program proceeds to step 5 and assigns the Vpp voltage at that point to variable Va.

Here, reading of Vpp voltage into the control software can be implemented using an apparatus of the configuration shown in FIG. 3, for example. FIG. 3 is explained later on. Next, in step 6 the voltage at n seconds from the endpoint of the cleaning step is read, in order to determine whether (T−n) seconds have elapsed or not on the timer started in step 3. Here, T is the step time of the cleaning step in the recipe. If (T−n) seconds have not yet elapsed, the software program stays in step 6 until (T−n) seconds elapse. Once (T−n) seconds have elapsed, the software program proceeds to step 7 and assigns the Vpp voltage at that point to variable Vb. Next, in step 8 the software program compares Va and Vb. If Va>Vb, the software program proceeds to the final step, or step 10, and ends the control process. If Va≦Vb, the software program determines that the cleaning rate is low and proceeds to step 9, in which it issues a warning (alarm) and ends the recipe and wafer lot processing. Thereafter, the software program proceeds to step 10 and ends the control process. This control process is a subroutine process called from a main control process of the plasma processing apparatus. The start step of this control process, or step 1, should ideally be called when a recipe process is started by the main control.

FIG. 3 is an example of configuration of plasma processing apparatuses used in one embodiment of the present invention. An AC voltage (1) is applied on an upper electrode (3) in a reaction chamber (2) at a specified frequency. A lower electrode (4) is connected to ground. The actual voltage applied between the electrodes is converted to a digital signal via an analog-digital converter (5) and read into control software (6). Although this configuration assumes that the upper and lower electrodes (3, 4) in the reaction chamber (2) are parallel plate electrodes, the present invention is not at all limited to this electrode specification.

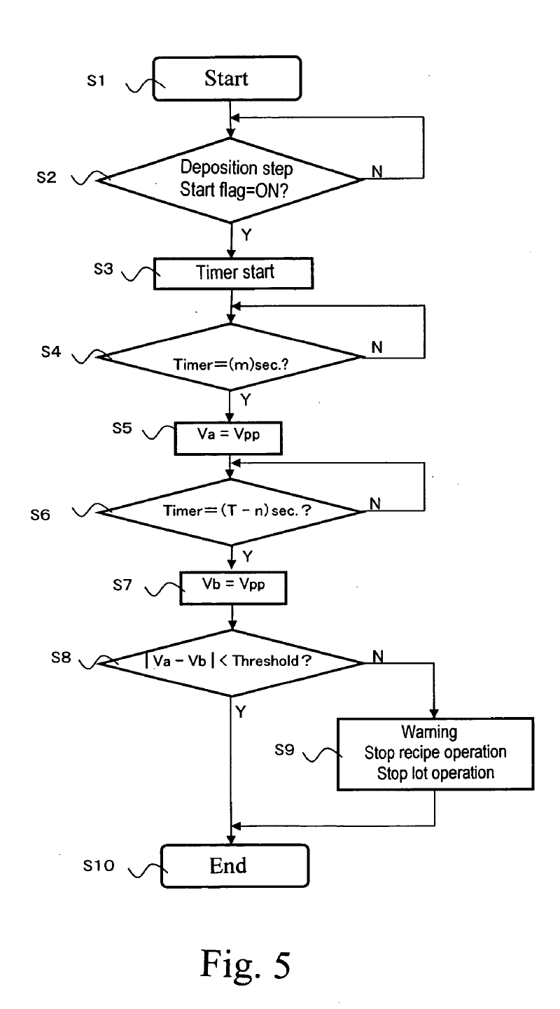

The above explained how abnormal operation of a cleaning process can be detected based on the present invention, but this method can also be applied to a deposition process. FIG. 4 shows a typical behavior of Vpp voltage during deposition (the present invention is not at all limited to this figure). Solid line C in the graph indicates the behavior of Vpp voltage during a normal deposition process. Here, the voltage behavior indicated by dotted line D in FIG. 4 sometimes occurs for some reason (abnormal operation of the deposition process). In this case, the same control flow chart in FIG. 2 can be used, with “Cleaning Step” in step 2 changed to “Deposition Step” and “Va>Vb” in the judgment algorithm in step 8 changed to “|Va−Vb|<Threshold” (to determine whether the absolute value of a difference between Va and Vb is smaller than a threshold). Here, the threshold is an allowable limit of error in voltage as determined by experimental data. A control flow chart for this deposition process is given in FIG. 5. Here, all steps are the same as those in the flow shown in FIG. 2, except for step 8.

To give you an example, Va and Vb in a cleaning process take 180 [V] and 170 [V], respectively, when the process is normal, and take 180 [V] and 200 [V], respectively, when the process is abnormal. In the case of a deposition process, both Va and Vb take 260 [V] when the process is normal, but they take 260 [V] and 250 [V], respectively, when the process is abnormal.

Based on the above, whether or not a cleaning process was implemented normally in a cleaning step during a recipe process on a plasma processing apparatus can be determined by measuring Vpp voltages at given two chronological points during the step and then comparing the measured voltages. If the cleaning process was not implemented normally, immediately a warning is issued and the recipe process and wafer lot processing are stopped, so that no more defective wafers will be manufactured. The apparatus can be inspected and serviced to identify the problem, which can then be corrected to restore a normal condition.

The present invention not only applies to a cleaning step in a recipe process, but it can also be applied to a deposition step in a recipe process, wherein abnormal operation of the reaction chamber can also be detected and the wafer lot processing can be stopped, as already described above.

In the aforementioned embodiments, examples of diagnosing and stopping cleaning and deposition processes on a plasma processing apparatus by using the apparatus alone were explained. In actual manufacturing lines, however, a semiconductor manufacturing apparatus is often connected to a host computer. If this is the case, the judgment processes shown in FIGS. 2 and 5 can be implemented on the host computer, not by the apparatus control software. In this case, A-D converted Va and Vb values are transmitted to the host computer, and the host computer compares the Va and Vb values based on a set of judgment criteria stored in the host computer and, if necessary, transfers a stop command to the plasma processing apparatus. Here, the plasma processing apparatus itself does not require any judgment function, and it only needs to provide a communication environment that enables transmission of Vpp voltages to the host computer.

The present invention is applicable either to a remote plasma process where F radicals for cleaning gas are generated in a separate unit and then introduced to the reaction chamber, or to an in-situ process where F radicals are generated inside the reaction chamber.

In one embodiment explained above, the electrodes (3, 4) in the reaction chamber (2) were assumed to be parallel plate electrodes. However, the present invention is not at all limited to semiconductor manufacturing apparatuses using parallel plate electrodes. Instead, it can be applied to semiconductor manufacturing apparatuses that use high-density plasma (HDP) or inductively coupled plasma (ICP), with parallel plate electrodes for diagnosis attached in the reaction chamber.

From the above, a plasma processing apparatus that, according to the present invention, compares the Vpp voltages at two chronological points measured during a cleaning process and detects abnormal operation of the reaction chamber is able to quickly detect abnormal operation of the apparatus during processing and stop the processing so that no more defective wafers will be manufactured. The apparatus can then be inspected and serviced to resolve the problem.

The present invention includes the above mentioned embodiments and other various embodiments including the following:

1) A plasma processing apparatus comprising software that detects abnormal operation during a semiconductor wafer manufacturing process, said software detecting abnormal operation of the reaction chamber by comparing the voltages between electrodes at given two chronological points measured during a cleaning process.

2) The plasma processing apparatus according to 1) above, wherein the software detects an abnormal operation of the reaction chamber by comparing the voltages between electrodes at given two chronological points measured during the cleaning process, and stops the cleaning process.

3) A plasma processing apparatus comprising software that detects abnormal operation during a semiconductor wafer manufacturing process, said software detecting abnormal operation of the reaction chamber during a deposition process.

4) The plasma processing apparatus according to 3) above, wherein the software detects abnormal operation of the reaction chamber based on a change in the voltage between electrodes during the deposition process.

5) The plasma processing apparatus according to 3) above, wherein the software detects abnormal operation of the reaction chamber by comparing the voltages between electrodes at given two chronological points measured during the deposition process.

6) The plasma processing apparatus according to 1) above, wherein the software detects an abnormal operation of the reaction chamber by comparing the voltages between electrodes at given two chronological points measured during the deposition process, and stops the deposition process.

7) The plasma processing apparatus according to 1) above, said apparatus transferring to a host computer the voltages between electrodes at given two chronological points measured during a cleaning step in a semiconductor wafer manufacturing process.

8) The plasma processing apparatus according to 3) above, said apparatus transferring to a host computer the voltages between electrodes at given two chronological points measured during a deposition step in a semiconductor wafer manufacturing process.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A method of detecting abnormal operation of a plasma process, comprising:
detecting a potential Vpp1 between an upper electrode and a lower electrode disposed parallel to each other in a reaction camber at a time T1 after the plasma process begins in the reaction chamber;
detecting a Vpp2 between the upper electrode and the lower electrode at a time T2 after T1;
comparing Vpp1 and Vpp2 to obtain an operation value; and
determining abnormal operation if the operation value is within a predetermined range.

2. The method according to claim 1, wherein the plasma process is a cleaning process.

3. The method according to claim 2, wherein the predetermined range of an operation value satisfies Vpp2≧Vpp1.

4. The method according to claim 1, wherein the plasma process is a film deposition process.

5. The method according to claim 4, wherein the predetermined range of an operation value satisfies |Vpp2−Vpp1|≧a threshold value.

6. The method according to claim 1, wherein T1 is at or near a midpoint of the plasma process.

7. The method according to claim 1, wherein T2 is at or near an endpoint of the plasma process.

8. The method according to claim 1, wherein the upper electrode is a showerhead, and the lower electrode is a susceptor.

9. The method according to claim 2, wherein the upper electrode is a showerhead, and the lower electrode is a susceptor, and the plasma process is remote plasma cleaning, said method further comprising applying an electric voltage between the upper electrode and the lower electrode for detecting Vpp1 and Vpp2.

10. The method according to claim 1, wherein the reaction chamber is a PECVD reaction chamber.

11. The method according to claim 1, further comprising stopping the plasma process when the abnormal operation is detected.

12. The method according to claim 1, further comprising transmitting the detected Vpp1 and Vpp2 to a host computer where the comparing step and the determining step are performed.

13. The method according to claim 1, further comprising selecting T1 and T2 before detecting Vpp1 and Vpp2, respectively, wherein T1 and T2 are the only points of time for detecting a potential between the upper electrode and the lower electrode for determining abnormal operation.

14. The method according to claim 1, which consists of the steps of detecting Vpp1, detecting Vpp2, comparing Vpp1 and Vpp2, and determining abnormal operation.
